(19) United States
(12) Patent Application Publication
(10) Pub. No.: US 2026/0353568 A1
(43) Pub. Date: Nov. 5, 2026

(54) METHOD FOR MANUFACTURING WIRING SUBSTRATE

(71) Applicant: IBIDEN CO., LTD., Gifu (JP)

(72) Inventors: Yuki NIWA, Gifu (JP); Hiroyuki KURAHASHI, Gifu (JP); Shogo FUKUI, Gifu (JP)

(73) Assignee: IBIDEN CO., LTD., Gifu (JP)

(21) Appl. No.: 19/391,397

(22) Filed: Nov. 17, 2025

(30) Foreign Application Priority Data
Dec. 5, 2024 (JP) 2024-212474

(51) Int. Cl. H05K 3/28; H05K 3/46

(52) U.S. Cl. CPC H05K 3/28; H05K 3/4644

(57) ABSTRACT

A method for manufacturing a wiring substrate includes laminating a resin insulating layer in a semi-cured state on a substrate, pressing the resin insulating layer laminated on the substrate toward the substrate, removing a peripheral edge portion of the resin insulating layer from the resin insulating layer laminated on the substrate, and forming a wiring layer on the resin insulating layer laminated on the substrate. The laminating of the resin insulating layer in the semi-cured state on the substrate includes positioning, on the substrate, the resin insulating layer having a dimension equal to or greater than a dimension of the substrate in at least one direction in a plan view, and the removing of the peripheral edge portion includes removing a portion of the resin insulating layer located on an outer side of a peripheral edge of the substrate in the plan view.

### CROSS-REFERENCE TO RELATED APPLICATIONS

The present application is based upon and claims the benefit of priority to Japanese Patent Application No. 2024-212474, filed Dec. 5, 2024, the entire contents of which are incorporated herein by reference.

### BACKGROUND OF THE INVENTION

### Field of the Invention

The present invention relates to a method for manufacturing a wiring substrate.

### Description of Background Art

Japanese Patent Application Laid-Open Publication No. 2021-163767 describes a method for manufacturing a printed wiring board. The entire contents of this publication are incorporated herein by reference.

### SUMMARY OF THE INVENTION

According to one aspect of the present invention, a method for manufacturing a wiring substrate includes laminating a resin insulating layer in a semi-cured state on a substrate, pressing the resin insulating layer laminated on the substrate toward the substrate, removing a peripheral edge portion of the resin insulating layer from the resin insulating layer laminated on the substrate, and forming a wiring layer on the resin insulating layer laminated on the substrate. The laminating of the resin insulating layer in the semi-cured state on the substrate includes positioning, on the substrate, the resin insulating layer having a dimension equal to or greater than a dimension of the substrate in at least one direction in a plan view, and the removing of the peripheral edge portion includes removing a portion of the resin insulating layer located on an outer side of a peripheral edge of the substrate in the plan view.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view illustrating an example of a wiring substrate manufactured using a method for manufacturing a wiring substrate according to an embodiment of the present invention;

FIG. 2 is a plan view of the wiring substrate illustrated in FIG. 1;

FIG. 3A is a cross-sectional view illustrating an example of a method for manufacturing a wiring substrate according to an embodiment of the present invention;

FIG. 3B is a cross-sectional view illustrating an example of a method for manufacturing a wiring substrate according to an embodiment of the present invention;

FIG. 3C is a plan view of the wiring substrate being manufactured as illustrated in FIG. 3B;

FIG. 3D is a cross-sectional view illustrating an example of a method for manufacturing a wiring substrate according to an embodiment of the present invention;

FIG. 3E is a plan view of the wiring substrate being manufactured as illustrated in FIG. 3D;

FIG. 3F is a cross-sectional view illustrating an example of a method for manufacturing a wiring substrate according to an embodiment of the present invention;

FIG. 3G is a cross-sectional view illustrating an example of a method for manufacturing a wiring substrate according to an embodiment of the present invention;

FIG. 3H is a cross-sectional view illustrating an example of a method for manufacturing a wiring substrate according to an embodiment of the present invention;

FIG. 3I is a cross-sectional view illustrating an example of a method for manufacturing a wiring substrate according to an embodiment of the present invention;

FIG. 3J is a cross-sectional view illustrating an example of a method for manufacturing a wiring substrate according to an embodiment of the present invention; and

FIG. 3K is a cross-sectional view illustrating an example of a method for manufacturing a wiring substrate according to an embodiment of the present invention.

### DETAILED DESCRIPTION OF THE EMBODIMENTS

Embodiments will now be described with reference to the accompanying drawings, wherein like reference numerals designate corresponding or identical elements throughout the various drawings.

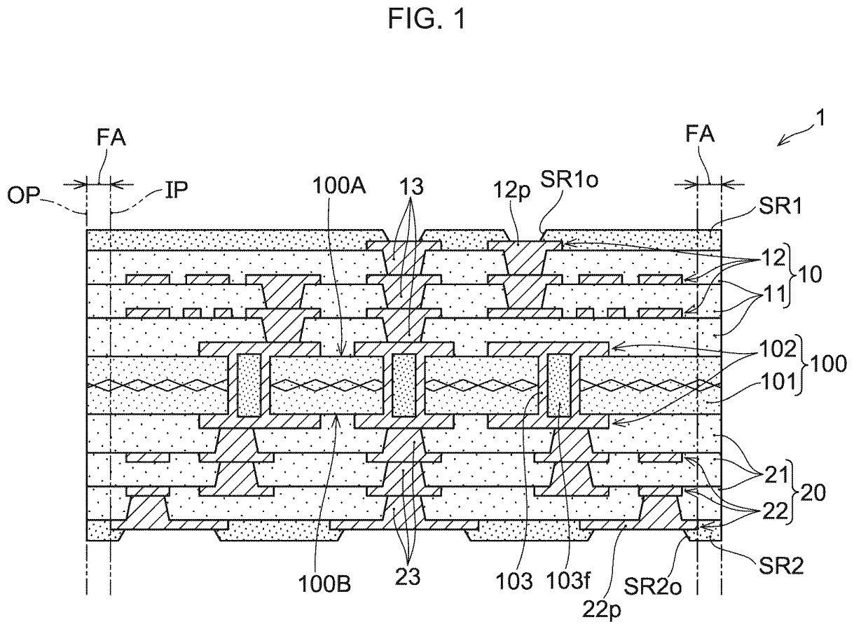

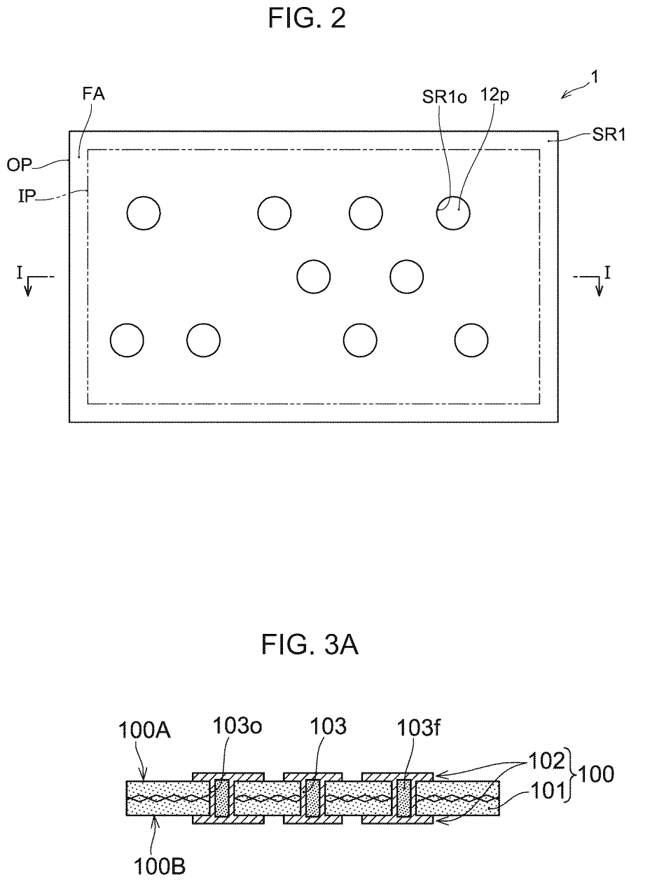

A method for manufacturing a wiring substrate according to an embodiment of the present invention is described with reference to the drawings. FIG. 1 illustrates a cross-sectional view of a wiring substrate 1, which is an example of a wiring substrate manufactured using the method for manufacturing a wiring substrate of the embodiment. FIG. 2 illustrates a plan view of the wiring substrate 1. The wiring substrate 1 in the illustrated example has a substrate 100 having one surface (100A) and another surface (100B) on an opposite side with respect to the one surface (100A).

On the one surface (100A) of the core substrate 100, a first build-up part 10 is formed, in which resin insulating layers 11 and wiring layers 12 are alternately laminated. On the other surface (100B), a second build-up part 20 is formed, in which resin insulating layers 21 and wiring layers 22 are alternately laminated. In the following description, the substrate 100 is also referred to as a core substrate 100. The core substrate 100 includes an insulating layer (core insulating layer) 101 and conductor layers (core conductor layers) 102. The resin insulating layers (11, 21) are hereinafter simply referred to as insulating layers (11, 21).

The wiring substrate 1 illustrated in FIG. 1 is merely an example of a wiring substrate manufactured using the method for manufacturing a wiring substrate of the embodiment. That is, using the method for manufacturing a wiring substrate of the embodiment, a wiring substrate can be manufactured that has a structure different from the laminated structure of the wiring substrate 1, and/or includes a number of wiring layers and resin insulating layers different from the number of wiring layers and resin insulating layers of the wiring substrate 1.

In describing the wiring substrate, a side farther from the core insulating layer 101 in a thickness direction of the wiring substrate 1 is referred to as “upper” or “upper side,” and a side closer to the core insulating layer 101 is referred to as “lower” or “lower side.” Further, for the resin insulating layers, the conductor layers, and the wiring layers, a surface facing away from the core insulating layer 101 is also referred to as an “upper surface,” and a surface facing the core insulating layer 101 is also referred to as a “lower surface.” Therefore, for example, in describing the elements that make up the core substrate 100, the first build-up part 10, and the second build-up part 20, a side farther from the core insulating layer 101 is referred to as an “upper side,” “upper,” “upper-layer side,” or simply “upper,” and a side closer to the core insulating layer 101 is referred to as a “lower side,” “lower,” “lower-layer side,” or simply “lower.” Further, in a plan view of the wiring substrate 1, in which the wiring substrate 1 is viewed in the thickness direction, a region closer to a center of the wiring substrate 1 is referred to as “inner” or an “inner side,” and a region farther from the center is referred to as “outer” or an “outer side.”

The core conductor layer 102 constituting the one surface (100A) of the core substrate 100 and the core conductor layer 102 constituting the other surface (100B) of the core substrate 100 are connected to each other by through conductors 103 that penetrate the core insulating layer 101 in the thickness direction. A hollow space on an inner side of each of the through conductors 103 is filled with a filler (103f).

The first build-up part 10 is composed of the resin insulating layers 11 and the wiring layers 12 that are alternately laminated on the one surface (100A) of the core substrate 100. The second build-up part 20 is composed of the resin insulating layers 21 and the wiring layers 22 that are alternately laminated on the other surface (100B) of the core substrate 100. Each resin insulating layer 11 of the first build-up part 10 includes via conductors 13 that connect two wiring layers 12 (or one wiring layer 12 and the conductor layer 102) that are respectively formed in contact with the two opposite surfaces of the resin insulating layer 11 in the thickness direction. Each resin insulating layer 21 of the second build-up part 20 includes via conductors 23 that connect two wiring layers 22 (or one wiring layer 22 and the conductor layer 102) that are respectively formed in contact with the two opposite surfaces of the resin insulating layer 21 in the thickness direction.

A solder resist layer (SR1) is formed on the first build-up part 10. A solder resist layer (SR2) is formed on the second build-up part 20. Openings (SR1o) are formed in the solder resist layer (SR1), and conductor pads (12p) of the outermost wiring layer 12 in the first build-up part 10 are exposed from the openings (SR1o). Opening (SR2o) are formed in the solder resist layer (SR2), and conductor pads (22p) of the outermost wiring layer 22 in the second build-up part 20 are exposed from the openings (SR2o).

The core insulating layer 101, the resin insulating layers 11 of the first build-up part 10, and the resin insulating layers 21 of the second build-up part 20 are each formed, for example, using an insulating resin such as epoxy resin, bismaleimide triazine resin (BT resin), phenol resin, or fluororesin. The insulating layers (101, 11, 21) may each contain a reinforcing material (core material) such as glass fiber and/or an inorganic filler such as silica or alumina. In the illustrated example, the core insulating layer 101 contains a core material, while the other resin insulating layers (11, 21) do not contain a core material.

The core conductor layers 102, the wiring layers (12, 22), the through conductors 103, and the via conductors (13, 23) can be formed using any metal such as copper or nickel. For example, the core conductor layers 102 and the wiring layers (12, 22) can each be formed of a metal foil such as a copper foil and/or a metal film formed by plating or sputtering. In FIG. 1, the core conductor layers 102, the wiring layers (12, 22), the through conductors 103, and the via conductors (13, 23) are illustrated in a simplified manner as each having a single-layer structure for ease of viewing, but can each have a multilayer structure including two or more layers. The core conductor layers 102 can each have a five-layer structure including a metal foil, a metal film layer (for example, an electroless copper plating film), and a plating film layer (for example, an electrolytic copper plating film). The wiring layers (12, 22), the through conductors 103, and the via conductors (13, 23) can each have a two-layer structure including, for example, a metal film layer (for example, an electroless copper plating film) and a plating film layer (for example, an electrolytic copper plating film).

The core conductor layers 102 and wiring layers (12, 22) of the wiring substrate 1 are each patterned to have predetermined conductor patterns. As will be described in detail later, in the method for manufacturing a wiring substrate of the embodiment, a relatively wide region of a wiring substrate to be manufactured can be used as a region where a wiring layer can be formed. FIG. 2 is a top view of the wiring substrate 1 illustrated in FIG. 1 as viewed from above the first build-up part 10. The wiring substrate 1 has a rectangular planar shape. FIG. 1 illustrates a cross section taken along a line (I-I) in FIG. 2. As illustrated in FIG. 2, the wiring substrate 1 has a region (FA) along its peripheral edge. The region (FA) is a region where the wiring layers (12, 22) cannot be formed. The region (FA) is provided along the entire peripheral edge of the wiring substrate 1.

According to the method for manufacturing a wiring substrate of the embodiment, it is possible to manufacture a wiring substrate in which a region (FA) where no wiring layer is formed is relatively small. As illustrated in FIG. 1, the wiring layers (12, 22) are not formed in the region (FA) occupying a predetermined range from the peripheral edge toward an inner side of the wiring substrate 1. A shortest distance between an outer edge (OP) (that is, the peripheral edge of the wiring substrate 1) and an inner edge (IP) of the region (FA) can be, for example, 15 mm. That is, the wiring layers (12, 22) can be formed in a region located 15 mm or more inward from the peripheral edge of the wiring substrate 1. In the illustrated example, the shortest distance between the outer edge (OP) and the inner edge (IP) of the region (FA) is substantially equal along all four sides of the rectangular wiring substrate 1 in plan view.

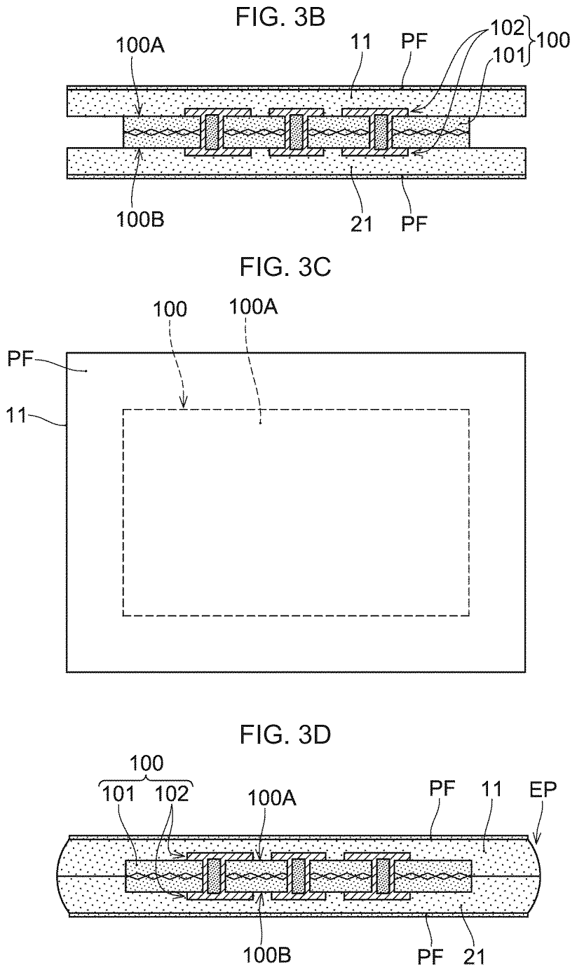

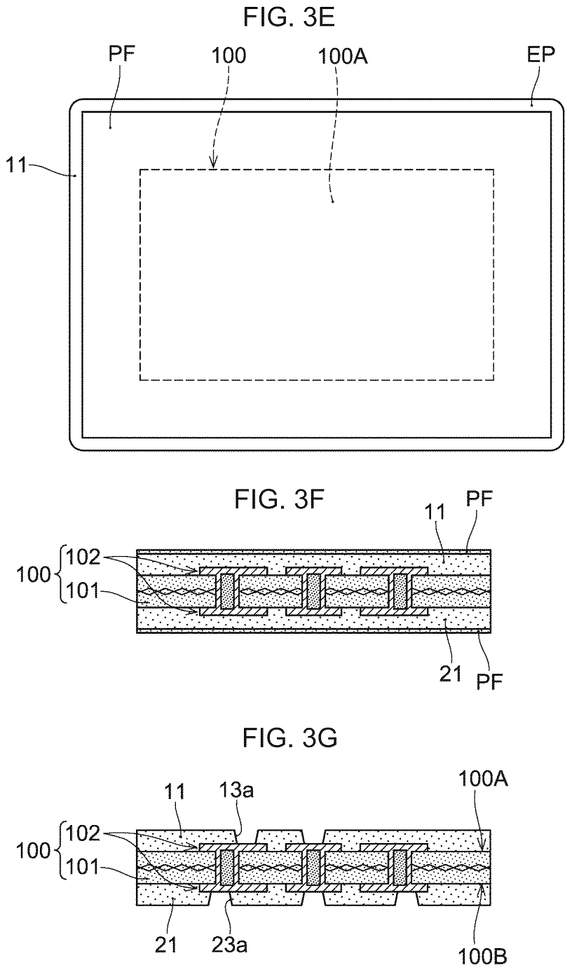

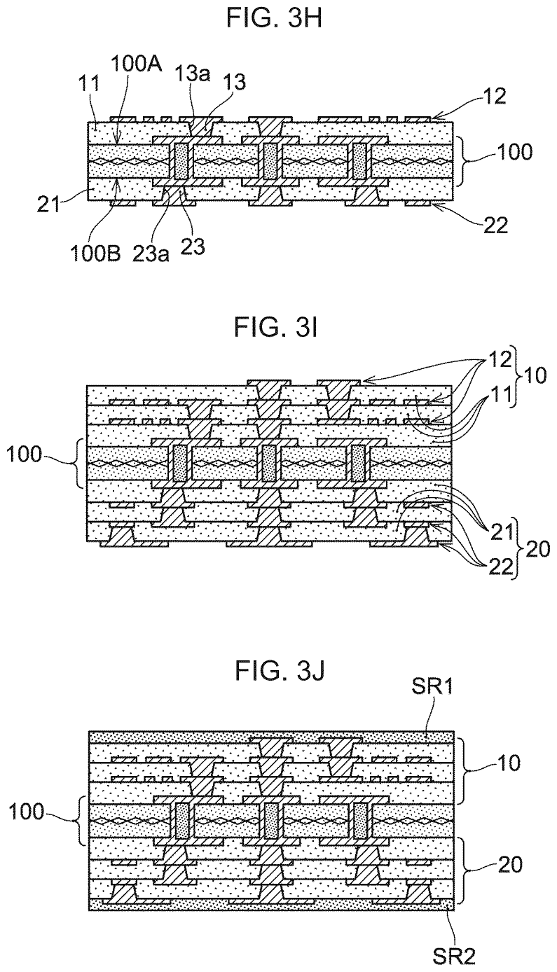

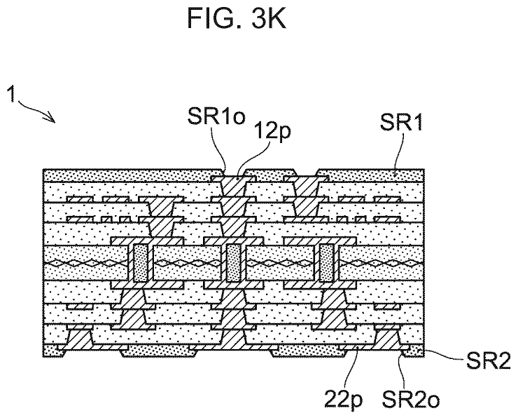

Next, an example of the method for manufacturing a wiring substrate of the embodiment is described with reference to FIGS. 3A to 3K using a case where the wiring substrate 1 of FIG. 1 is manufactured as an example. Among FIGS. 3A to 3K, FIGS. 3A to 3D and 3F to 3K illustrate cross-sections corresponding to FIG. 1, and the conductor layers and wiring layers are each illustrated as a single layer.

First, a substrate is prepared. As illustrated in FIG. 3A, the core substrate 100 having the one surface (100A) and the other surface (100B) on an opposite side with respect to the one surface (100A) is prepared. In preparing the core substrate 100, for example, a double-sided copper-clad laminate in which a metal foil (copper foil) is provided on the surfaces of the core insulating layer 101 is prepared. Through holes (1030) are formed in the double-sided copper-clad laminate, for example, by drilling, and a metal film layer, for example, an electroless copper plating film, is formed on inner walls of the through holes (1030) and on the upper surface of the metal foil. On the metal film layer, a plating film layer, for example, an electrolytic copper plating film, is formed by electrolytic plating using the metal film layer as a power feeding layer. Thus, the through conductors 103 are formed.

Interiors of the through conductors 103, which are formed on the inner walls of the through holes (103o), are filled with the filler (103f), for example, by injecting an epoxy resin into the inner sides of the through conductors 103. After the filler (103f) is solidified, on upper surface of the filler (103f) and the plating film layer, a metal film layer and a plating film layer are further formed. As a result, although each illustrated as a single layer in the drawing, the core conductor layers 102 each having a five-layer structure including a metal foil, a metal film layer, a plating film, a metal film layer, and a plating film layer are respectively formed on the two surfaces of the core insulating layer 101. Then, by patterning the core conductor layers 102 using a subtractive method, a core substrate 100 having predetermined conductor patterns is obtained.

Next, resin insulating layers are laminated on the substrate. Semi-cured resin insulating layers (11, 21) are laminated on the core substrate 100. Specifically, as illustrated in FIGS. 3B to 3F, a semi-cured resin insulating layer 11 is laminated on the one surface (100A) of the core substrate 100, and a resin insulating layer 21 is laminated on the other surface (100B). Hereinafter, the resin insulating layer 11 laminated on the one surface (100A) is also referred to as the first resin insulating layer 11, and the resin insulating layer 21 laminated on the other surface (100B) is also referred to as the second resin insulating layer 21.

The first resin insulating layer 11 and the second resin insulating layer 21 are formed of a material containing a resin such as a thermosetting resin (such as an epoxy resin) or a thermoplastic resin (such as a fluororesin). As illustrated in FIG. 3B, the first resin insulating layer 11 and the second resin insulating layer 21 are positioned on the core substrate 100 in a semi-cured state, that is, in a so-called B-stage condition. A protective film (PF) is provided on an upper surface of each of the first resin insulating layer 11 and the second resin insulating layer 21. Examples of the protective film (PF) include polyethylene terephthalate (PET) and polyethylene naphthalate (PEN) films. The protective film (PF) is attached over the entire upper surface of each of the first resin insulating layer 11 and the second resin insulating layer 21.

In the manufacturing method of the embodiment, a semi-cured resin insulating layer positioned on the substrate has a dimension equal to or greater than that of the substrate in at least one of its extending directions (in plan view). In the example of manufacturing the wiring substrate 1 described herein, the first resin insulating layer 11 and the second resin insulating layer 21 positioned on the core substrate 100 have dimensions greater than those of the core substrate 100 in all their extending directions. The first resin insulating layer 11 and the second resin insulating layer 21 may have dimensions equivalent to those of the core substrate 100 in their extending directions.

FIG. 3C illustrates a plan view of a state illustrated in FIG. 3B, as viewed from above the one surface (100A) of the core substrate 100. As illustrated in FIG. 3C, the first resin insulating layer 11 has dimensions greater than those of the core substrate 100 in all directions in plan view. The first resin insulating layer 11 is positioned to cover the entire one surface (100A) of the core substrate 100 and protrude outward from the peripheral edge of the core substrate 100 along the entire perimeter (that is, along the entire peripheral edge).

In the plan view illustrated in FIG. 3C, the peripheral edge of the second resin insulating layer 21 located on a far side of the drawing overlaps with the peripheral edge of the first resin insulating layer 11. That is, similar to the first resin insulating layer 11, the second resin insulating layer 21 also has dimensions greater than those of the core substrate 100 in all directions in plan view. The second resin insulating layer 21 is positioned to cover the entire other surface (100B) (see FIG. 3B) of the core substrate 100 and protrude outward from the peripheral edge of the core substrate 100 along the entire perimeter. Therefore, the peripheral edge of the first resin insulating layer 11, the peripheral edge of the second resin insulating layer 21, and the peripheral edges of the protective films (PF) provided on the upper surfaces of the first resin insulating layer 11 and the second resin insulating layer 21 are all located on an outer side of the core substrate 100.

In a process of thermocompression-bonding the first resin insulating layer 11 to the core substrate 100, which will be described later, it is preferable that the first resin insulating layer 11 on the core substrate 100 be formed to have a more uniform thickness. From this point of view, it is preferable that the extent to which the first resin insulating layer 11 protrudes outward from the peripheral edge of the core substrate 100 (a shortest distance, in plan view, from the peripheral edge of the core substrate 100 to the peripheral edge of the first resin insulating layer 11) be substantially uniform along the entire perimeter (that is, along all four sides) of the first resin insulating layer 11. Similarly, from the same point of view, it is preferable that the extend to which the second resin insulating layer 21 protrudes outward from the peripheral edge of the core substrate 100 be substantially uniform along the entire perimeter of the second resin insulating layer 21.

In the method for manufacturing a wiring substrate of the embodiment, a substrate that serves as a base for a resin insulating layer is not limited to a so-called core substrate such as the core substrate 100 described above. For example, it may be a laminate in which insulating layers and wiring layers formed using a build-up method are alternately laminated, or it may be a substrate having only an insulating layer. A substrate that serves as a base for a resin insulating layer may also be a silicon substrate, a ceramic substrate, or a glass substrate.

Next, the first resin insulating layer 11 and the second resin insulating layer 21, together with the protective films (PF), are subjected to heating and pressing against the core substrate 100. The resin constituting the first resin insulating layer 11 and the second resin insulating layer 21 is softened by the heating, and pressure is applied from the upper side of the protective films (PF) toward the one surface (100A) or the other surface (100B) of the core substrate 100 by a pressing plate (not illustrated). As a result, the first resin insulating layer 11 is thermocompression-bonded to the entire one surface (100A) of the core substrate 100, and the second resin insulating layer 21 is thermocompression-bonded to the entire other surface (100B) of the core substrate 100.

A result of the thermocompression-bonding of the first resin insulating layer 11 and the second resin insulating layer 21 to the core substrate 100 is a state illustrated in FIGS. 3D and 3E. FIG. 3E is a plan view of the state illustrated in FIG. 3D as viewed from above the one surface (100A). When the first resin insulating layer 11 and the second resin insulating layer 21 are pressed against the core substrate 100 in a softened state due to heating, the softened resin of the first resin insulating layer 11 and the second resin insulating layer 21 is pushed outward. As a result, the softened resin of the first resin insulating layer 11 and the second resin insulating layer 21 flows around the peripheral edge of the core substrate 100 and covers side surfaces that constitute the peripheral edge of the core substrate 100.

By pressing the first resin insulating layer 11 and the second resin insulating layer 21 against the core substrate 100 in a softened state due to heating, the first resin insulating layer 11 and the second resin insulating layer 21 come into contact with each other. Specifically, as illustrated in FIG. 3D, a portion of the first resin insulating layer 11 located on an outer side of the peripheral edge of the core substrate 100 and a portion of the second resin insulating layer 21 located on an outer side of the peripheral edge of the core substrate 100 come into contact with each other. When the softened resin of the first resin insulating layer 11 and the softened resin of the second resin insulating layer 21 come into contact with each other, the softened resin is further pushed and spread outward, and as illustrated, a locally deformed portion (expanded portion) (EP) that protrudes outward from the peripheral edge of the protective film (PF) is formed. As illustrated in FIG. 3E, the expanded portion (EP) can be formed so as to protrude outward from the protective film (PF) along the entire perimeter of the first resin insulating layer 11 and the second resin insulating layer 21 (that is, along all four sides of the protective film (PF)).

In the method for manufacturing a wiring substrate of the embodiment, during thermocompression bonding of the resin insulating layers to the substrate, local deformation of the resin insulating layers caused by the flow of the softened resin occurs on an outer side of the substrate. No local deformation of the resin insulating layers occurs in portions overlapping the substrate in the thickness direction. A wider region of the substrate can be used as a wiring substrate.

After the first resin insulating layer 11 and the second resin insulating layer 21 are respectively thermocompression-bonded to the surfaces of the core substrate 100, the semi-cured first resin insulating layer 11 and second resin insulating layer 21 are fully cured. By the full curing, the resin constituting the first resin insulating layer 11 and the second resin insulating layer 21 is cured to a final stage of curing, a so-called C-stage state. The first resin insulating layer 11 and the second resin insulating layer 21 are fully cured, for example, by heating at a temperature suitable for the full curing of the resin constituting the first resin insulating layers 11 and the second resin insulating layer 21 for an appropriate time. Without being limited to thermal curing, the first resin insulating layer 11 and the second resin insulating layer 21 may also be fully cured using any other method such as ultraviolet irradiation.

Next, peripheral edge portions of the resin insulating layers are removed. As illustrated in FIG. 3F, portions of the first resin insulating layer 11 and the second resin insulating layer 21 located on an outer side of the peripheral edge of the core substrate 100 are removed together with the protective films (PF) by cutting. The portions of the first resin insulating layer 11 and the second resin insulating layer 21 located on an outer side of the peripheral edge of the core substrate 100 in plan view are removed, and as illustrated, the entire peripheral edge (side surface) of the core substrate 100 is exposed. For the removal by cutting of the portions of the first resin insulating layer 11 and the second resin insulating layer 21 located on an outer side of the peripheral edge of the core substrate 100, any method can be used, such as router processing or processing using a roller blade such as a dicing saw.

Next, as illustrated in FIG. 3G, via through holes (13a) are formed in the first resin insulating layer 11 on the one surface (100A) of the core substrate 100, and via through holes (23a) are formed in the second resin insulating layer 21 on the other surface (100B) of the core substrate 100. The via through holes (13a, 23a) are formed, for example, by irradiation with laser such as CO₂ laser or ultraviolet laser. The via through holes (13a, 23a) are respectively formed in the first resin insulating layer 11 and the second resin insulating layer 21 while the protective films (PF) (see FIG. 3F) remain provided. Since the via through holes (13a, 23a) are formed while the protective films (PF) are still provided, adhesion of resin debris generated from the first resin insulating layer 11 and the second resin insulating layer 21 to the surfaces of the first resin insulating layer 11 and the second resin insulating layer 21 can be prevented. Further, since laser is irradiated onto the surfaces of the protective films (PF) and not directly onto the surfaces of the first resin insulating layer 11 and the second resin insulating layer 21, formation of excessively large via through holes (13a, 23a) in the first resin insulating layer 11 and the second resin insulating layer 21 due to impact caused by laser irradiation can be prevented.

The formed via through holes (13a, 23a) can be subjected to a treatment (so-called desmear treatment) to remove resin residues generated during the formation of the via through holes (13a, 23a). The resin residue removal treatment can be performed while the first resin insulating layer 11 and the second resin insulating layer 21 still have the protective films (PF) provided thereon. The resin residue removal treatment may be a wet process that includes, for example, immersion in a dissolving solution such as a permanganate solution. Further, the resin residue removal treatment may be a dry process without using a dissolving solution. A dry process for removing resin residues may be, for example, a plasma treatment using a plasma gas such as argon, tetrafluoromethane, a mixed gas of tetrafluoromethane and oxygen, or sulfur hexafluoride.

After that, the protective films (PF) are removed using any method, and a state illustrated in FIG. 3G is formed. The protective films (PF) can be peeled off, for example, simply by respectively pulling the protective films (PF) in directions opposite to the resin insulating layers (11, 21). Further, the protective films (PF) may be removed by dissolution using an appropriate solvent.

In the state illustrated in FIG. 3G, the first resin insulating layer 11 completely covers the one surface (100A) of the core substrate 100, and the second resin insulating layer 21 completely covers the other surface (100B). The first resin insulating layer 11 and the second resin insulating layer 21 extend, in plan view, to the peripheral edge of the core substrate 100. In the manufacturing method described in Japanese Patent Application Laid-Open Publication No. 2021-163767, the resin composition layer is not formed up to the peripheral edge of the inner-layer substrate, and a portion of the inner-layer substrate near the peripheral edge that is not covered by the resin composition layer is thought unavailable for use as part of the printed wiring board. In contrast, according to the method for manufacturing a wiring substrate of the embodiment, the entire region of each surface of the substrate (core substrate) orthogonal to the thickness direction is covered by a resin insulating layer. Therefore, it is thought that even a region near the peripheral edge of the substrate can be effectively utilized as part of the printed wiring board.

In the state illustrated in FIG. 3G, the upper surfaces of the resin insulating layers (11, 21) each have relatively good flatness over a relatively wide region, including the region near the peripheral edge in plan view. As a result, the wiring layers (12, 22), which will be described later with reference to FIG. 3H, can be respectively formed over relatively wide ranges on the upper surfaces of the resin insulating layers (11, 21). Specifically, the wiring layers (12, 22) can be formed in an inner region at a predetermined distance or more, for example, 15 mm or more, from the peripheral edges of the resin insulating layers (11, 21) (that is, from the peripheral edge of the core substrate 100).

Next, as illustrated in FIG. 3H, the via through holes (13a, 23a) penetrating the resin insulating layers (11, 21) are filled with a conductor to form the via conductors (13, 23), and at the same time, wiring layers (12, 22) are formed integrally with the via conductors (13, 23). The wiring layer 12 is formed on the resin insulating layer 11 that covers the one surface (100A) of the core substrate 100. The wiring layer 22 is formed on the resin insulating layer 21 that covers the other surface (100B) of the core substrate 100. The wiring layers (12, 22) are formed in the regions where formation of the wiring layers (12, 22) is possible, which is at a predetermined distance or more inward from the peripheral edges of the resin insulating layers (11, 21), as described above.

The wiring layers (12, 22) and the via conductors (13, 23) can be formed, for example, using a general semi-additive method. That is, the wiring layers (12, 22) and the via conductors (13, 23) can be formed by: forming a seed layer (not illustrated) made of a metal film such as copper by electroless plating or sputtering on the surfaces of the resin insulating layers (11, 21) and on inner surfaces of the via through holes (13a, 23a); forming a plating resist (not illustrated) having appropriate openings on the formed seed layer; and forming an electrolytic plating film (not illustrated) within the openings of the plating resist using the seed layer as a power feeding layer. Then, by peeling off the plating resist and removing exposed portions of the seed layer by quick etching or the like, the wiring layers (12, 22) having desired conductor patterns are formed.

Subsequently, similar processes to those described with reference to FIGS. 3B to 3H, including: positioning the resin insulating layers (11, 21) onto the core substrate 100, thermocompression bonding them to the core substrate 100, removal of the portions extending outward from the peripheral edge of the core substrate 100, and forming the via conductors (13, 23) and the wiring layers (12, 22), are repeated any number of times on the upper sides of the resin insulating layers (11, 21). That is, in the method for manufacturing a wiring substrate, multiple resin insulating layers may be laminated on the substrate. In such a case, a portion of each resin insulating layer extending outward from the peripheral edge of the substrate can be removed by cutting before forming a wiring layer on the resin insulating layer. The first build-up part 10 and the second build-up part 20 are formed, and a state illustrated in FIG. 3I is formed.

Next, as illustrated in FIG. 3J, the solder resist layer (SR1) is formed on the first build-up part 10, and the solder resist layer (SR2) is formed on the second build-up part 20. The solder resist layers (SR1, SR2) are made of, for example, photosensitive epoxy resin or polyimide resin, and can be formed by spray coating, curtain coating, lamination, or the like.

Next, as illustrated in FIG. 3K, the openings (SR1o) are formed in the solder resist layer (SR1) to expose the conductor pads (12p), and the openings (SR2o) are formed in the solder resist layer (SR2) to expose the conductor pads (22p). The openings (SR1o, SR2o) are formed by exposure and development using masks with appropriate opening patterns. On exposed surfaces of the conductor pads (12p, 22p), a surface protection film (not illustrated) made of Au, Ni/Au, Ni/Pd/Au, solder, or heat-resistant preflux may be formed by electroless plating, solder leveling, spray coating, or the like. Through the above processes, the wiring substrate 1 is completed.

The method of manufacturing a wiring substrate of the embodiment is not limited to the method described with reference to FIGS. 3A-3K . For example, in the example illustrated in FIGS. 3D and 3E, it is also possible that the deformed portions (expanded portions) (EP) do not protrude outward beyond the protective films (PF), and outer edges of the first resin insulating layer 11 and the second resin insulating layer 21 on an outer side of the core substrate 100 coincide with the peripheral edges of the protective films (PF) located on an outer side of the core substrate 100. Further, it is also possible that, using the method for manufacturing a wiring substrate of the embodiment, a wiring substrate having a structure different from the laminated structure illustrated in the drawings or a wiring substrate including a number of resin insulating layers different from that illustrated in the drawings is manufactured. The method for manufacturing a wiring substrate of the embodiment includes at least: positioning and pressing a resin insulating layer on a substrate, the resin insulating layer having a dimension equal to or greater than a dimension of the substrate in at least one direction in plan view; and removing a peripheral edge portion of the resin insulating layer located on an outer side of a peripheral edge of the substrate in plan view. For example, when multiple resin insulating layers are laminated on the substrate, the peripheral edge portions of the resin insulating layers may be removed by cutting the peripheral edge portions of the multiple layers all at once. Any process other than the processes described above may be added, and any of the processes described above may be omitted. In the description of the manufacturing method exemplified by the manufacture of the wiring substrate 1 described above, an example was illustrated in which the resin insulating layers are laminated on both sides of the substrate. However, the resin insulating layers to be laminated on the substrate only need to be laminated on at least one side of the substrate.

Japanese Patent Application Laid-Open Publication No. 2021-163767 describes a method for manufacturing a printed wiring board. A first resin sheet, in which a first support is provided on a first resin composition layer, is bonded onto an inner-layer substrate, and the first resin composition layer is thermally cured to form an insulating layer. At an end portion (peripheral edge portion) of the first resin sheet, the first support has a margin portion that is not in contact with the first resin composition layer.

In the method of Japanese Patent Application Laid-Open Publication No. 2021-163767, it is thought that an end portion (peripheral edge portion) of the inner-layer substrate is not bonded to the first resin composition layer, and thus, no insulating layer is formed at the peripheral edge portion of the inner-layer substrate. It is thought that the peripheral edge portion of the inner-layer substrate cannot be used as part of the printed wiring board.

A method for manufacturing a wiring substrate according to an embodiment of the present invention includes: laminating a resin insulating layer in a semi-cured state on a substrate; pressing the resin insulating layer toward the substrate; removing a peripheral edge portion of the resin insulating layer; and forming a wiring layer on the resin insulating layer. The laminating of the resin insulating layer in the semi-cured state on the substrate includes positioning, on the substrate, the resin insulating layer having a dimension equal to or greater than a dimension of the substrate in at least one direction in plan view, and the removing of the peripheral edge portion includes removing a portion of the resin insulating layer located on an outer side of a peripheral edge of the substrate in plan view.

According to an embodiment of the present invention, it is thought that a peripheral edge region of the wiring substrate in plan view can be effectively utilized.

Obviously, numerous modifications and variations of the present invention are possible in light of the above teachings. It is therefore to be understood that within the scope of the appended claims, the invention may be practiced otherwise than as specifically described herein.

1. A method for manufacturing a wiring substrate, comprising:
laminating a resin insulating layer in a semi-cured state on a substrate;
pressing the resin insulating layer laminated on the substrate toward the substrate;
removing a peripheral edge portion of the resin insulating layer from the resin insulating layer laminated on the substrate; and
forming a wiring layer on the resin insulating layer laminated on the substrate,
wherein the laminating of the resin insulating layer in the semi-cured state on the substrate includes positioning, on the substrate, the resin insulating layer having a dimension equal to or greater than a dimension of the substrate in at least one direction in a plan view, and the removing of the peripheral edge portion includes removing a portion of the resin insulating layer located on an outer side of a peripheral edge of the substrate in the plan view.

2. The method for manufacturing a wiring substrate according to claim 1, further comprising:
laminating a second resin insulating layer on the substrate in a semi-cured state on a substrate such that the resin insulating layer is laminated on a first surface of the substrate and that the second resin insulating layer is laminated on a second surface of the substrate on an opposite side with respect to the first surface of the substrate.

3. The method for manufacturing a wiring substrate according to claim 2, wherein the pressing of the resin insulating layer includes bringing a portion of the first resin insulating layer located on an outer side of the peripheral edge of the substrate and a portion of the second resin insulating layer located on an outer side of the peripheral edge of the substrate into contact with each other.

4. The method for manufacturing a wiring substrate according to claim 1, further comprising:
positioning a protective film on the resin insulating layer laminated on the substrate such that the protective film is on an opposite side with respect to the substrate, and the pressing of the insulating layer includes pressing the protective film positioned on the resin insulating layer toward the substrate.

5. The method for manufacturing a wiring substrate according to claim 4, further comprising:
removing the protective film from the resin insulating layer after the removing of the peripheral edge portion of the resin insulating layer.

6. The method for manufacturing a wiring substrate according to claim 1, further comprising:
positioning a protective film on the resin insulating layer laminated on the substrate such that the protective film has a dimension equal to or greater than a dimension of the substrate and is on an opposite side with respect to the substrate.

7. The method for manufacturing a wiring substrate according to claim 1, wherein the resin insulating layer has dimensions equal to or greater than dimensions of the substrate in all directions in the plan view.

8. The method for manufacturing a wiring substrate according to claim 1, wherein the removing of the portion of the resin insulating layer located on an outer side of the peripheral edge of the substrate includes exposing the peripheral edge of the substrate.

9. The method for manufacturing a wiring substrate according to claim 1, wherein the wiring layer is formed in a region that is 15 mm or more inward from the peripheral edge of the substrate.

10. The method for manufacturing a wiring substrate according to claim 1, further comprising:
positioning a protective film on the resin insulating layer laminated on the substrate such that the protective film has a dimension equal to or greater than a dimension of the substrate and is on an opposite side with respect to the substrate and that a peripheral edge of the protective film is on an outer side of the peripheral edge of the substrate.

11. The method for manufacturing a wiring substrate according to claim 2, further comprising:
positioning a protective film on the resin insulating layer laminated on the substrate such that the protective film is on an opposite side with respect to the substrate, and the pressing of the insulating layer includes pressing the protective film positioned on the resin insulating layer toward the substrate.

12. The method for manufacturing a wiring substrate according to claim 11, further comprising:
removing the protective film from the resin insulating layer after the removing of the peripheral edge portion of the resin insulating layer.

13. The method for manufacturing a wiring substrate according to claim 2, further comprising:
positioning a protective film on the resin insulating layer laminated on the substrate such that the protective film has a dimension equal to or greater than a dimension of the substrate and is on an opposite side with respect to the substrate.

14. The method for manufacturing a wiring substrate according to claim 2, wherein the resin insulating layer has dimensions equal to or greater than dimensions of the substrate in all directions in the plan view.

15. The method for manufacturing a wiring substrate according to claim 2, wherein the removing of the portion of the resin insulating layer located on an outer side of the peripheral edge of the substrate includes exposing the peripheral edge of the substrate.

16. The method for manufacturing a wiring substrate according to claim 2, wherein the wiring layer is formed in a region that is 15 mm or more inward from the peripheral edge of the substrate.

17. The method for manufacturing a wiring substrate according to claim 2, further comprising:
positioning a protective film on the resin insulating layer laminated on the substrate such that the protective film has a dimension greater than a dimension of the substrate and is on an opposite side with respect to the substrate and that a peripheral edge of the protective film is on an outer side of the peripheral edge of the substrate.

18. The method for manufacturing a wiring substrate according to claim 3, further comprising:
positioning a protective film on the resin insulating layer laminated on the substrate such that the protective film is on an opposite side with respect to the substrate, and the pressing of the insulating layer includes pressing the protective film positioned on the resin insulating layer toward the substrate.

19. The method for manufacturing a wiring substrate according to claim 18, further comprising:
removing the protective film from the resin insulating layer after the removing of the peripheral edge portion of the resin insulating layer.

20. The method for manufacturing a wiring substrate according to claim 3, further comprising:
positioning a protective film on the resin insulating layer laminated on the substrate such that the protective film has a dimension equal to or greater than a dimension of the substrate and is on an opposite side with respect to the substrate.
